(19) United States
(12) Patent Application Publication
(10) Pub. No.: US 2016/0215415 A1
(43) Pub. Date: Jul. 28, 2016

(54) SAPPHIRE THINNING AND SMOOTHING USING HIGH TEMPERATURE WET PROCESS

(71) Applicant: MT SYSTEMS, INC., Fremont, CA (US)

(72) Inventors: Thomas W. HALLORAN, Fremont, CA (US); Karen A. REINHARDT, Fremont, CA (US); Thomas M. VUKOSAV, Fremont, CA (US)

(21) Appl. No.: 14/917,345

(22) PCT Filed: Sep. 16, 2014
(86) PCT No.: PCT/US2014/055960

§ 371 Date: Mar. 8, 2016

Related U.S. Application Data
(60) Provisional application No. 61/877,819, filed on Sep. 13, 2013.

(51) Int. Cl. C30B 35/00; C30B 29/20; C30B 33/10

(52) U.S. Cl. CPC C30B 35/007; C30B 33/10; C30B 29/20

(57) ABSTRACT

A method for thinning a sapphire substrate is provided that includes placing a sapphire substrate in a pre-heat tank to raise the temperature of said sapphire substrate; placing the pre-heated sapphire substrate in a wet etch tank comprising a solution including at least one of H₂SO₄ and H₃PO₄ at a temperature ranging between 200-400° C.; monitoring the time to determine when to remove said sapphire substrate from said wet etch tank to thin said sapphire substrate; and placing the sapphire substrate in a cool-down tank to lower the temperature of the sapphire substrate. The method provides for a high throughput and is cost effective process, thereby allowing for the adoption of sapphire in high volume and lower cost applications.

### CROSS REFERENCE TO RELATED APPLICATIONS

This application claims priority to U.S. Provisional Application No. 61/877,819 filed Sep. 16, 2013, the contents of which is incorporated herein by reference as if explicitly and fully expressed herein.

### FIELD OF THE INVENTION

The present invention in general relates to substrate and substrate production, and in particular to a process and system for high throughput production of sapphire substrates.

### BACKGROUND OF THE INVENTION

Sapphire, which is composed of aluminum oxide (Al₂O₃), may be found naturally or may be manufactured for industrial or decorative purposes in large crystal boules. The remarkable hardness of sapphires has led to the use of this material in practical applications including infrared optical components, such as laser rods and waveguides; high-durability transparent windows; wristwatch crystals and low-friction movement bearings; optical fibers; and thin electronic substrates, which are used as an insulating substrates for solid-state electronics and integrated circuits, such as light emitting diodes (LED) and silicon on sapphire (SOS) devices that also require a high conductivity of heat that sapphire can provide. Additionally, where chemical-resistance is needed for optical and industrial components; sapphire is well suited because of its inertness to chemical etch.

One application of synthetic sapphire is optics in which a high level of transparency is required. Sapphire has high transparency to wavelengths of light between ultraviolet and infrared (150 nm (UV) to 5500 nm (IR)), but is also extraordinarily resistant to abrasion and scratches, and is significantly stronger than such as compared to silicate glass windows or lenses and has significantly larger window of transparency than other optical material. Sapphire has a value of 9 on the Mohs scale of mineral hardness and is the hardest natural substance next to diamond (with a value of 10). Sapphire has an extremely high melt temperature (2030° C.) and is unaffected by all aqueous-based chemicals except some very hot acids, caustics, and fluorides.

Transparent sapphire substrates or other products are made from high-purity sapphire boules, typically seeded in the a-crystal orientation that have been grown and then cored at specific crystal orientation, typically along a crystal axis plane, for example; the a-plane. The cores are sliced, typically by wire sawing, into substrates with approximately the desired thickness and ground or lapped to remove the saw-damaged surface, and finally polished to the desired surface finish. Sapphire can be polished to a wide range of surface finishes depending on the application. For standard optical windows to provide minimum birefringence the a-plane (1120) is chosen, for LED applications, typically the c-plane (0001) is chosen.

The use of sulfuric acid in a combination with phosphoric acid has been known since at least the early 2000's to be an effective etchant for Al₂O₃, and in particular the c-plane (0001) crystal orientation of sapphire. Early use of the combination of H₂SO₄ and H₃PO₄ or H₃PO₄ alone was to decorate the sapphire surface due to the preferential etching of the sapphire surrounding defects—either due to metallic contamination or crystal dislocations.

As taught in U.S. Pat. No. 7,579,202, the use of combination solutions of H₂SO₄ and H₃PO₄ or H₃PO₄ to etch groves into a sapphire substrate that pattern the surface and increase the surface area, and thus the brightness of light emitting diodes (LEDs). Subsequent U.S. Pat. Nos. (7,781,790, 8,101,447, 8,236,591) have also utilized this chemistry combination for etching patterned sapphire substrates (PSS) into c-plane sapphire. The reason for using this chemistry was to isotropically etch the c-plane sapphire along the r-plane to form pyramids into the sapphire, using a mask. However, limitations existed with respect to temperatures. There are no examples of smoothing surfaces; the intent was to roughen the surface to obtain more surface area. The need for smooth surfaces is different for LED devices, compared to display devices, which this disclosure is targeted towards. The improvement of the single crystal sapphire material purity has improved, and the ability to smooth the sapphire without having a high density of defects has allowed the use of this chemistry for smoothing, without creating a high density of surface defects from the preferential etching, further allowing for use of this chemistry for high-transparency, low reflectance optical devices.

While the use of sapphire for glass-like surfaces is widely recognized for the reasons mentioned, the adoption of sapphire in mass production applications such as display covers for consumer devices, such as cellular phones, has met with little acceptance due to the low throughput and high costs of production associated with sapphire manufacture and processing. Furthermore, the use of H₂SO₄, H₃PO₄, and H₃PO₄ for thinning sapphire is presently not known for producing display devices that use sapphire windows.

Thus, there exists a need for a process and apparatus for producing sapphire-based products that have a high throughput and is cost effective, thereby allowing for the adoption of sapphire in high volume and lower cost applications.

### BRIEF DESCRIPTION OF THE DRAWINGS

The present invention is further detailed with respect to the following drawings. These figures are not intended to limit the scope of the present invention but rather illustrate certain attributes thereof.

FIG. 1 is a schematic view of an etch process bath according to an embodiment of the invention;

FIG. 2 shows a process flow for patterned sapphire substrate (PSS) wet etching according to embodiments of the invention;

FIG. 3 shows a process flow for sapphire etching using a aqueous immersion process according to embodiments of the invention;

FIG. 4 is a process schematic depicting the sequential position of the inventive etch process in a first embodiment particularly well suited for sapphire wafer/window formation;

FIG. 5 is a process schematic depicting the sequential position of the inventive etch process in a first embodiment particularly well suited for sapphire wafer/window formation from unground “as-sawed” wafers that are polished to a desired finish;

FIG. 6 is a process schematic depicting the sequential position of the inventive etch process in a first embodiment particularly well suited for sapphire wafer/window formation from unground “as-sawed” wafers that are etched to smooth;

FIGS. 7A-7D are block diagrams of a docking base station and modules for carrying out various configurable etching processes according to embodiments of the invention;

FIG. 8 is a graph showing PSS etch rates versus concentrations of H₂SO₄ to H₃PO₄ at a temperature of 280° C. for single sided polished with an oxide mask according to embodiments of the invention;

FIG. 9A illustrates etching rates for sapphire substrate thinning (SST) according to embodiments of the invention;

FIG. 9B is a graph showing SST etch rates versus concentrations of H₂SO₄ to H₃PO₄ at a temperature of 285 and 300° C. for double sided thinning;

FIG. 9C is a graph showing SST and sapphire substrate smoothing (SSS) etch rates with and without agitation at 300° C.;

FIGS. 10A and 10B are optical photographs of the sapphire smoothing surface (SSS) without (FIG. 10A) and with (FIG. 10B) agitation; and

FIG. 11 is a plot of reflectance percentage as a function to wavelength for various sapphire planes as annotated and relative to a conventional reference wafer: c-plane double side polished (DSP), where single side polished is denoted as SSP.

### SUMMARY OF THE INVENTION

An inventive method for thinning a sapphire substrate is provided and includes placing a sapphire substrate in a pre-heat tank to raise the temperature of said sapphire substrate; placing the pre-heated sapphire substrate in a wet etch tank comprising a solution including at least one of H₂SO₄ and H₃PO₄ at a temperature ranging between 200-400° C.; monitoring the time to determine when to remove said sapphire substrate from said wet etch tank to thin said sapphire substrate; and placing the sapphire substrate in a cool-down tank to lower the temperature of the sapphire substrate. One or more sapphire substrate orientations may be used in the invention, illustratively including c, r, a and m plane orientations.

An inventive system for producing sapphire substrates is also provided and includes a docking base station configured to accept docking modules and controls; and a single point for facility connections to utilities and supply lines on said docking base station. The docking modules include one or more high temperature process modules, a pre-heat module, a cooling module, and a dryer/rinse module.

Additionally, a substrate composition is provided which includes a sapphire substrate having a thickness of between 50 and 400 microns and a reflectance of at wavelengths between 380 nm and 1000 nm.

Finally, an inventive method for smoothing a sapphire substrate is provided which includes placing said sapphire substrate in a pre-heat tank to raise the temperature of the sapphire substrate; placing the pre-heated sapphire substrate in a wet etch tank comprising a solution including at least one of H₂SO₄ and H₃PO₄ at a temperature ranging between 200-400° C.; monitoring time to determine when to remove the sapphire substrate from the wet etch tank to smooth the substrate; and placing the sapphire substrate in a cool-down tank to lower the temperature of the sapphire substrate. One or more sapphire substrate orientations may be used in the invention, illustratively including c, r, a and m plane orientations.

### DESCRIPTION OF THE INVENTION

The present invention has utility in the processing of sapphire to form substrates or other laser cut or wire sawed products. An inventive process and system is provided for high throughput or any production level of sapphire substrates using an aqueous chemical etching process. Through the invocation of processing temperatures above 200° C., processing times for thinning and etching are decreased so as to provide an overall increase in throughput. Sapphire substrates obtained from the inventive process and system can be made ultra-thin with superior reflective properties, as compared to sapphire substrates produced by conventional processes. The ability to manufacture ultra-thin sapphire substrates with embodiments of the inventive process and system allow for flexible substrates and membranes that may be curved or other otherwise contoured. Unlike conventional processing of sapphire substrates which is slow and relies on physical abrading, grinding, lapping, and/or polishing of a substrate with only limited results due to the multi-faceted surface of the sapphire substrate that leads to unevenly treated high or low spots, such as pits, scratches, and buildup of amorphous Al₂O₃ on the substrate, the inventive process and system avoids the need for abrasive grinding, lapping, or polishing by using substrates without abrasive polishing, etc. Certain embodiments of the inventive process use agitation to minimize these localized physical removal effects, creating a very smooth, highly transparent surface. Agitation can also increase the etching rate of c-plane sapphire. The ability of the inventive process to use unpolished or unground wire sawed wafer (“as cut”), has a surprising result of superior planarity and smoothness and thereby reducing the time of, or in some embodiments entirely eliminating the polishing step of chemical mechanical polishing (CMP). In still other embodiments, the time of, or in still other embodiments entirely eliminating sapphire thinning through grinding.

Sapphire substrate etching applications provided by embodiments of the inventive sapphire production system may include patterned sapphire substrate PSS (etching), sapphire substrate dicing, sapphire thinning, sapphire smoothing, sapphire texturing, and sapphire substrate edge rounding.

It is to be understood that in instances where a range of values are provided that the range is intended to encompass not only the end point values of the range but also intermediate values of the range as explicitly being included within the range and varying by the last significant figure of the range. By way of example, a recited range of from 1 to 4 is intended to include 1-2, 1-3, 2-4, 3-4, and 1-4 and also 4:1, 3:1, 3:2, and 2:1.

Sapphire material etching applications provided by embodiments of the inventive sapphire production system may include sapphire component manufacturing such as thinning, shaping, rounding, texturing, smoothing, scoring, substrate dicing, etc., while eliminating or reducing the amount of lapping, grinding, texturing, and finishing, such as polishing. Examples of end products include sapphire plasma tubes, touch screens, protection screens, process boats, lenses, etc.

High temperature applications for the H₂SO₄ and H₃PO₄ solutions used in certain embodiments include resist stripping, organic contamination removal, organic film removal, certain metallic contamination removal, and ceramic etching and finishing. In some embodiments of the present invention these acids are contacted with materials at temperatures between 200 and 400° C., while in still other embodiments, the temperature at which reaction occurs with a target substrate is 240 and 320° C. The volume ratio of aqueous solutions of H₂SO₄:H₃PO₄ typically varies from 0.1-10:1 and in some particular embodiments is between 0.5-3:1. Additionally, H₂SO₄ or H₃PO₄ each alone can be used for specific applications in addition to the mixtures. Typical aqueous concentration of commercially available sulfuric acid H₂SO₄ is about 96-98 weight percent (wt %) and phosphoric acid H₃PO₄ is about 85 wt %.

Observations have shown that H₂SO₄:H₃PO₄ ratio at 1:1, although having a lower etch rate than the higher ratios such as 3:1, yield a smoother surface with less pits. The physical mechanism is not known, however, it is speculated that the slower etch rate does not allow the defects to be preferentially etched, which is the source of the pitting. The defects may be crystal disruptions or metallic contamination.

Sapphire substrate smoothing (SSS) is accomplished on substrates or manufactured parts, and can be successfully performed on various planes of the sapphire work piece. The SSS decreases peak to valley roughness due to sawing applications, and for top surface smoothing and removal of saw damage and the amorphous sapphire buildup. SSS can be used for edge smoothing after cutting, to minimize or replace polishing. The SSS process can minimize peaks and pits and minimize preferential etching around defects; including both metallic contamination and crystal dislocations.

Sapphire substrate thinning performed with embodiments of the invention provide for rapid and cost effective thin sapphire substrates. The no-stress thinning inventive process has the ability to thin all sapphire planes: a, c, r, m. It is appreciated that the rate and uniformity of the thinning varies with factors including the sapphire plane, contaminant concentration, acid solution, and agitation. The thinning process is readily combined with smoothing applications. It is further appreciated that specific sapphire substrates are intentionally pitted in a controlled and uniform matter. Such pitted sapphire has applications where internal reflectance is favored such as, for example, LEDs. Furthermore, embodiments of the inventive process provide an increased etch rate with improved uniformity, as compared to lower temperature etch processes. SST may be performed after sawing where the minimal thickness is limited by dimensions of the saw. SST replaces lapping or grinding which create surface damage and stress. Lapping and grinding are limited to substrate thickness due to stress; these processes can create physical stress points in the crystalline sapphire that can propagate first into lattice dislocations and then more severely into cracks, in some cases immediately, while in other cases the cracks are latent and appear at later stages of the manufacturing process. Thinning of substrates with initial thickness of 200 to 700 μm down to 50 μm has been demonstrated with embodiments of the invention. Wafers thinned to below 80 μm in some embodiments are supported so as to inhibit creasing or rolling up due to surface tension. Thin substrates may also “float” in chemical bath, and fixtures to support thin substrates have been developed.

SSS minimizes surface roughness, and also has the ability to minimize preferential etching around defects both metallic and dislocations. By choosing the appropriate volume ratio of H₂SO₄:H₃PO₄, the crystal plane-selective etching can be attenuated. Using the addition of H₃PO₄ in H₂SO₄ at the appropriate temperature, the smoothness can be maximized and the formation of undesirable Al₂(SO₄)₃ can be minimized. In certain embodiments, when Al₂(SO₄)₃ is formed, it is removed by etching. The etching process assists in the solubilization of the precipitate Al₂(SO₄)₃. One method is using phosphoric alone, H₃PO₄, to etch the Al₂(SO₄)₃ by replacing the SO₄²⁻ group with PO₄³⁻ group, thus rendering the ions soluble in the H₃PO₄ solution. The process can be performed at temperatures between 120-250° C. The smoothing that occurs during the H₂SO₄ processing step (a 5:1 ratio for example) is retained.

It is appreciated that in specific embodiments of the present invention, H₃PO₄ alone, at the elevated temperatures afford comparable results. In addition to H₃PO₄ and H₂SO₄, additives include solvents, solvents that form azeotropes with water, chelating agents, surfactants, other acids, salts of acids, and combinations thereof. Such additives being stable at the process temperatures of 200-400° C.

Embodiments of the inventive process and system can be used for sapphire texturing (STX) to increase peak to valley roughness, act to replace pattern sapphire substrate (PSS) etching with a no pattern process, create a translucent frosted surface, for increased reflectance due to light reflecting off the surface, for increased surface area for bonding and other applications, to maximize peaks and maximize pits, to control preferential etching around defects including both metallic and dislocations.

Embodiments of the inventive process and system can be used for sapphire substrating, wafering, and dicing. During substrating and wafering, saw damage may be removed and edge rounding performed. During the dicing process kerf damage may be removed that results from laser sawing, as well as slag removal resulting from both diamond and laser sawing. Furthermore, partial sawing or scoring and then etching with the H₂SO₄/H₃PO₄ acid process may be used to minimize long sawing times.

An acid media is required to etch sapphire (Al₂O₃). A total reaction given by

Al₂O₃+3H₂O→2Al(OH)₃

Al(OH)₃+3H⁺→Al³⁺+2H₂O where

Without intending to be bound by a particular theory, Al(OH)₃, AlPO₄, and Al(H₂PO₄)₃ are soluble in the etchant solution, while Al₂(SO₄)₃ is insoluble due to the reaction of the aluminum cation, Al³⁺ with the anions, SO₄²⁻ or PO₄³⁻ in the aqueous solution due to the high concentrations thereof in the inventive etching solutions at 200-400° C. Thus, a mixture of H₂SO₄ with H₃PO₄ is able to maintain a high temperature and thus control the boiling point and also favorably minimize insoluble products, while ensuring a wide process window. In at least one embodiment, agitation is performed to help with the chemical transport mechanism to convect the insoluble impurities away from the surface. The agitation not only improves the etch rate but also decreases the amount of Al₂(SO₄)₃ that precipitates on the surface at high H₂SO₄: H₃PO₄ ratio, for example at 5:1.

Agitation may be accomplished by 1) mechanical action, 2) bubbling gas through the solution, or 3) by applying sonic energy. For example, bubbling gas: N₂ or other inert gas (i.e., Ar, He) may be bubbled into the acid solution to cause agitation of the liquid. Typically, a gas diffuser plate is placed at the bottom of the bath, and the gas flows into the liquid, causing “boiling” of the liquid. This mechanism displaces the chemical that is close to the substrate with new chemical and removes the products of the reactant. Sonic energy agitation may use: ultrasonic energy or other sonic energy that can also cause displacement of the fluid next to the substrate. The addition of gas along with the sonic energy allows a smaller quantity of gas to be used.

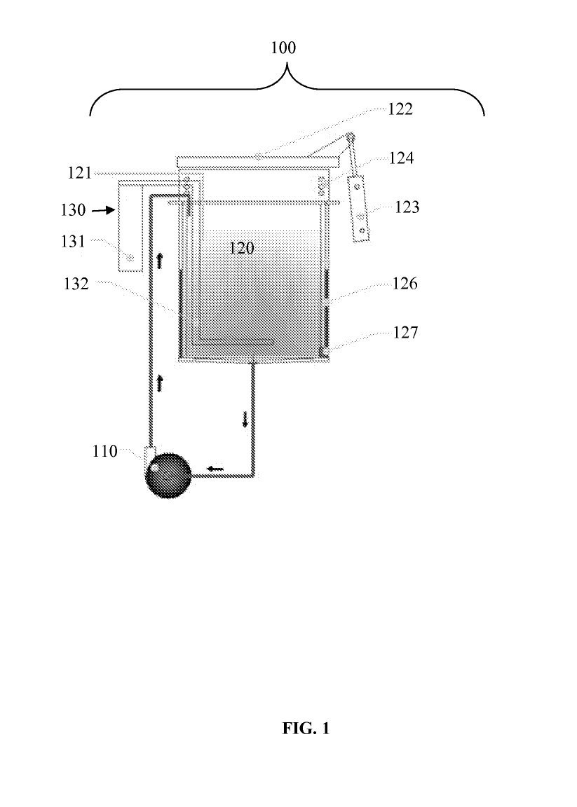

Referring now to the figures, FIG. 1 is a schematic view of an embodiment of an etch process bath 100 according to the present invention is shown. The etch process bath 100 includes, a high temperature recirculation pump 110, a process tank 120 and an agitator 130. The process tank 120 has a lid 122 and a liquid level indicator 121. In at least one embodiment of the present invention the lid 122 further includes a lid actuator 123. The process tank 120 optionally includes several additional components, including condensing coils 124, a blanket heater 126, an RTD temperature sensor 127, or combinations thereof. In at least one embodiment, the agitator 130 includes a servo 131 and an agitator arm 132.

The high temperature etch bath 100 heats the chemicals to a temperature between 200-400° C. The process tank 120 is made of materials compatible with acidic chemistry and high temperatures such as quartz, or ternary carbides of the formula Mₙ₊₁AXₙ, where M independently in each occurrence is Ti, Nb, Zr, Hf, Nb, Cr, Ta, V, Sc, or Mo; n is 1, 2 or 3; A independently in each occurrence is Al P, Pb, Ga, S, In As, Cd, Ge, Tl, or Al with the proviso that M and A are not the same; and X is C or N independently in each occurrence. In at least one embodiment the process tank 120 is a quartz tank. In certain inventive embodiments, auto-dosing is used to maintain constant temperature and concentrations in concert with temperature, level, and thickness sensors during sapphire processing. The bath is configured with a drain port for easy disposal of bath chemistry. In certain inventive embodiments, chemistries within the bath are recirculated and/or agitated at temperatures above 200° C. to eliminate localized etching effects. In certain embodiments, the high temperature recirculation pump 110 is a quartz-lined pump. Agitation is also done to eliminate localized etching effects due to concentration or temperature gradients and minimize bubble stiction. Chemical fume capture and control is accomplished through ergonomic design and air control management, and with a recondensor at high temperatures to minimize and capture fumes and minimize chemical usage. Both double and single sided etching may be performed in the bath as a batch process. It is appreciated a robotic agitator arm is readily controlled to move a wafer holder in various patterns of movement illustratively including vertical, horizontal, arcuate, rotary, and a combinations thereof. For single sided etching a custom carrier to protect unetched side is used.

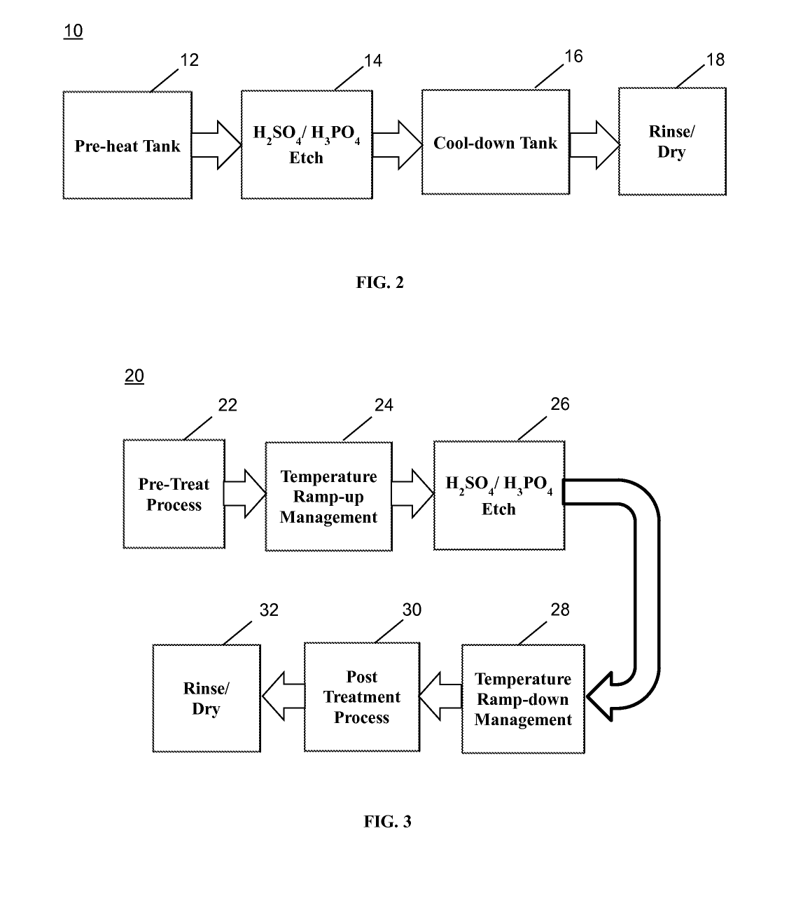

FIG. 2 shows an embodiment of a process flow 10 for patterned sapphire substrate (PSS) wet etching. The pre-heat tank 12 and cool-down tank 16 are used to avoid thermal stress to the substrate to be treated. Multiple H₂SO₄/H₃PO₄ etching tanks 14 or other tanks can be added to platform. A rinse/dry step 18 concludes the process. A HF etching tank (not shown) can be included for removal of SiO₂ etching mask.

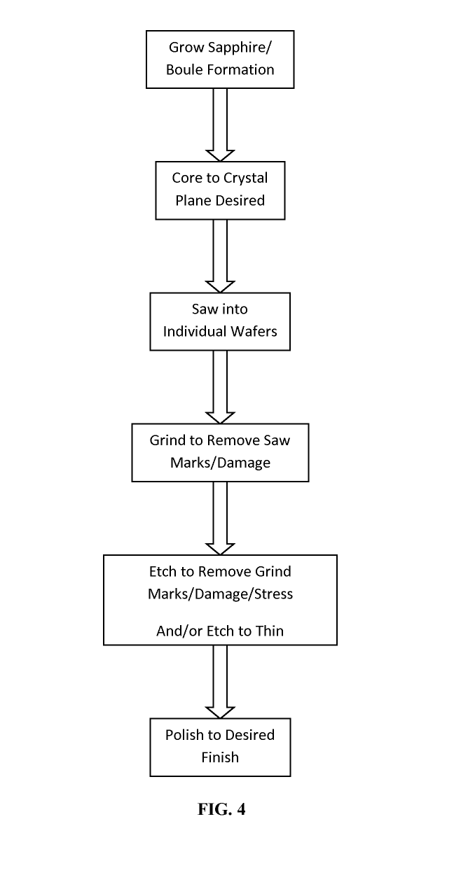

FIG. 3 shows an embodiment of a process flow 20 for sapphire etching immersion. During the pre-treat process 22 the substrate is pre-cleaned to remove metallic contamination and particles. It is noted that pre-clean for organic removal is not needed, since the H₂SO₄/H₃PO₄ acid process is sufficient to remove the organics. Pretreatment and post-treatment can include neutralization of acids, and metal contamination or particle removal. The temperature ramp-up 24 and ramp down management 28 are pre-heat and cool-down tanks to avoid thermal stress. The H₂SO₄/H₃PO₄ etch step 26 chemistries are determined based upon the application. Multiple H₂SO₄/H₃PO₄ etching tanks or other tanks can be added to platform. Additives may be added to the etching chemistry for specific functions. A HF etching tank (not shown) can be included for removal of SiO₂ etching mask, or other post treatment processes 30 and a rinse/dry 32.

The use of thermal management such as the temperature ramp-up 24 and ramp down management 28 in the form of pre-heat and cool-down tanks in FIG. 2 to avoid thermal stress is critical with sapphire. Sapphire has high coefficient of thermal expansion (CTE of 5.0-6.6 E-6/K) while SiO₂ is five to six times lower than sapphire (CTE of 1 E-6/K). If the temperature in a bath is raised or lowered at too high a rate, the sapphire material expands or shrinks rapidly and can fracture. Therefore, uniform temperature management is needed across the entire substrate as a gradual ramp or stepwise function.

While a single bath is typically adequate, multiple baths can achieve multiple effects. For example, a first bath can achieve a high etch rate for thinning, while a second bath may be used for smoothing a thick substrate which requires both thinning and smoothing. In a second example, a first bath provides preliminary smoothing, while a second bath provides final smoothing for any substrate with extreme saw damage. In a third example, three baths are used, where the first bath is for a high etch rate for thinning or removal of saw damage, the second bath is for preliminary smoothing, and the third bath is for final smoothing. Other combinations of baths may be used depending upon starting substrate characteristics and desired objectives.

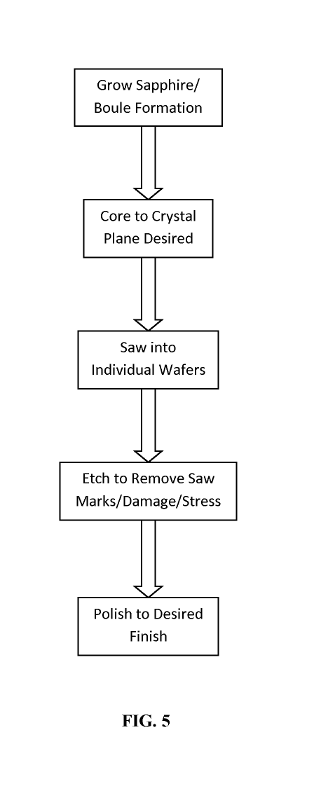

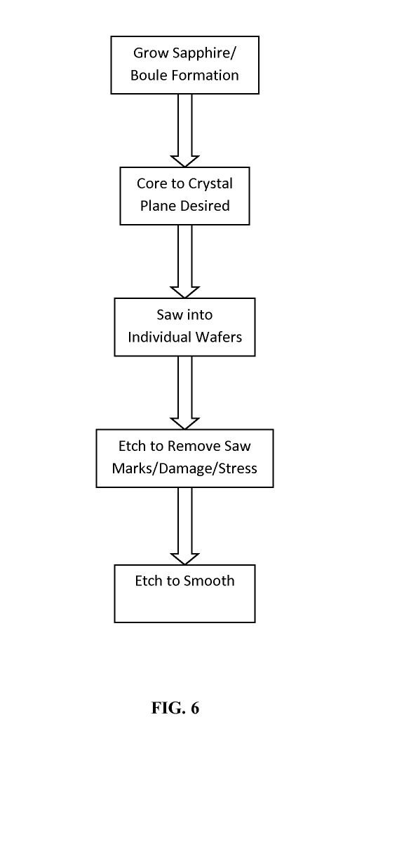

FIGS. 4-6 are process schematics that illustrate various steps surrounding the inventive processes as detailed with respect to FIG. 2 or 3. In FIGS. 4-6, those process steps beginning with the word “Etch” denote an inventive process.

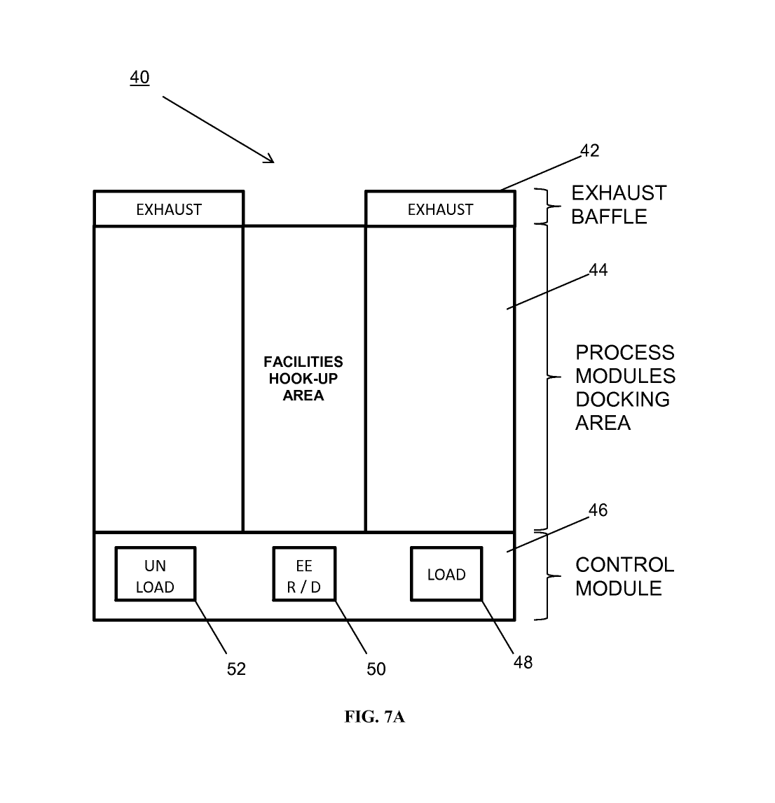

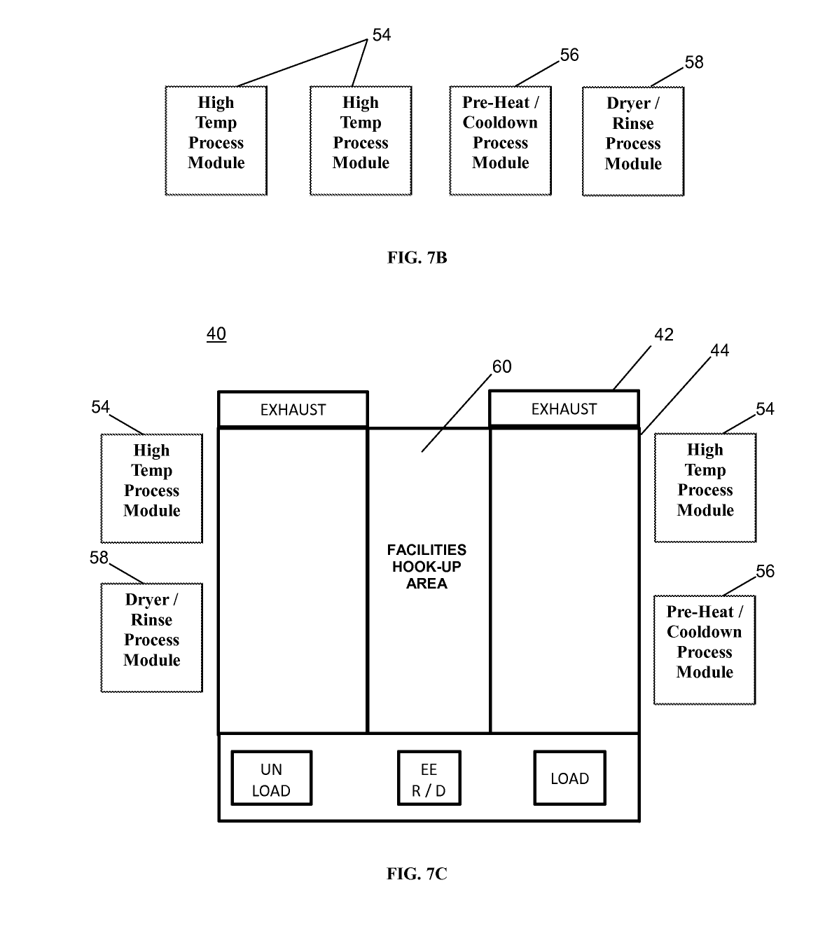

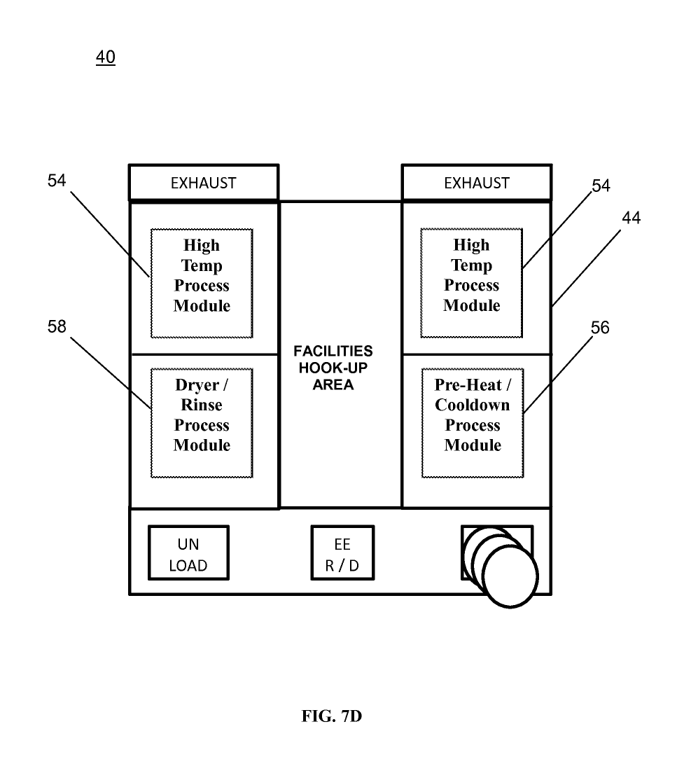

FIGS. 7A-7D are block diagrams of a docking base station 40 and modules for carrying out various configurable etching processes with a modular design configured for bulkhead installation for a controlled mini environment. The base station features an overhead mounted robot, and is configurable for future mobile docking modules and expansion. A process cart docking module provides for less downtime during repairs. The docking base station 40 may have a single point for facility connections 60 to utilities and supply lines (electrical, waste drainage, N₂/CDA, exhaust, etc.). Various controls such as fume capture and condensation may be configured with the base station 40 in the exhaust 42.

FIG. 7B illustrates mobile process docking modules including a high temperature process module 54, a pre-heat/cool-down process module 56, and a dryer/rinse module 58. The high temperature process module 54 tanks may operate from 200-400° C., with cooling coils, an automatic lid, with a quartz cool-down tank. The pre-heat/cool-down process module 56 may have a quartz tank with an operating temperature up to 180° C. The dryer/rinse module 58 may be a nitrogen (N₂) based with deionized water (DIW), and has no moving parts with a quick dump feature. FIG. 7C and FIG. 7D show alternative embodiments of the mobile inventive process docking modules (54, 56, 58) of FIG. 7B engaged in the base station 40 at the process module docking area 44.

Without being bound to a particular theory, it is believed that large, thick pieces of sapphire have a higher propensity for breakage than small thin substrates. Thus, at least one embodiment of the present invention manages the temperature of the sapphire work piece to prevent breakage. Several methods of temperature management may be employed which are widely used in the art. In at least one embodiment air cooling is used. By way of a non-limiting example, gradually raising the post-process work piece from the high-temperature bath at a rate of 1 mm to 1 cm per minute. It should be appreciated that the larger the work piece, the slower the rate of rise, thus the slower the cooling. Due to air cooling, the work piece has chemicals coated on the surface. The work piece can be post-processed once the core is cooled to within 60° C. of room temperature. Process processing can include cleaning the precipitate Al₂(SO₄)₃ from the surface or rinsing with water to remove the chemical or both. In at least one embodiment, leaving the work piece in the processing bath and cooling down gradually can also accomplish the same rate of cooling. Optional techniques for cooling can include multiple temperature baths, where the work piece is gradually lowered in temperature from the process temperature in 60° C. increments or smaller temperature increments. In at least one embodiment, an oven is used to accomplish the same cooling. In addition, and by way of a non-limiting example, multiple ovens or furnaces are used with gradually lower temperatures between which the work piece is sequentially transferred to obtain gradual cooling. It should be appreciated that heating a large work piece requires the same care with respect to temperature management. Heating at too high of a rate will cause breakage due to the large thermal coefficient of expansion. Heating can be accomplished in an oven, in the process bath, or on any apparatus that can uniformly heat (or cool) the work piece.

Sapphire material etching applications provided by embodiments of the inventive sapphire production system operate at elevated temperatures, and the very high temperatures of the baths do not lend themselves to normal metrology methods for concentration measurement. For example, dip probes would be prone to destruction under the high temperatures, and it is infeasible to use conventional flow cell commonly used for concentration monitors. However, the use of quartz baths in embodiments allows a line of sight for optical measurement. Absorption measurements through quartz using spectrometers and light sources are feasible for concentration determinations. In addition, in situ surface roughness may be measured, as well as in situ thickness measurement is possible.

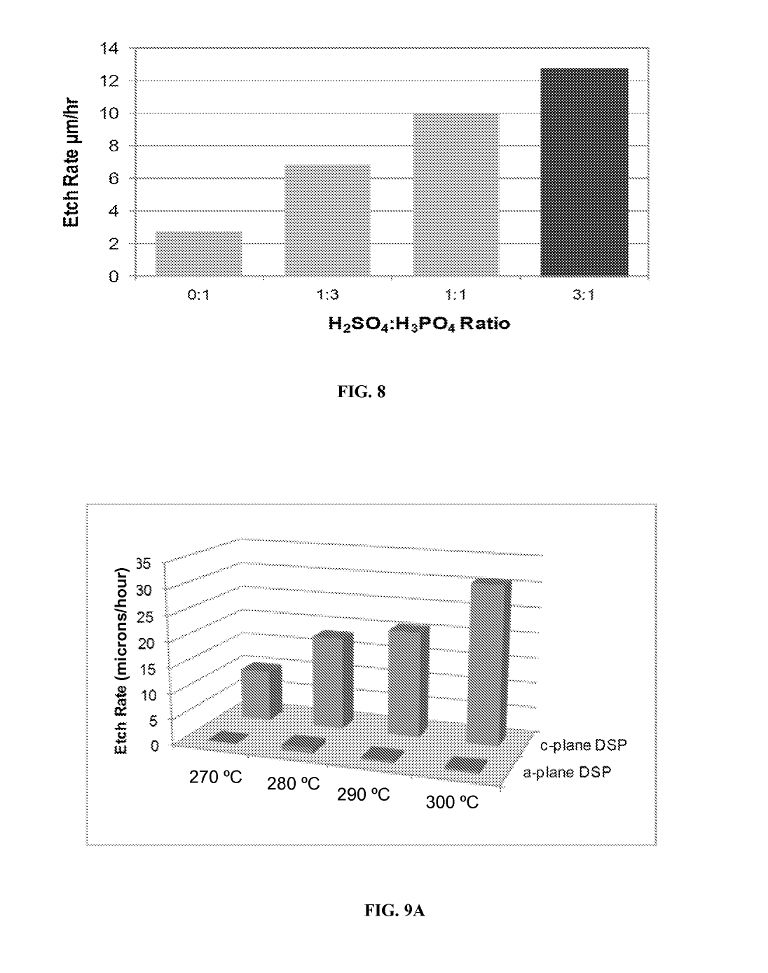

Etching rates are dependent on concentration and temperature. FIG. 8 is a graph showing PSS etch rates of C-plane sapphire versus concentrations of H₂SO₄ to H₃PO₄ at a temperature of 280° C. for single sided polished with an oxide mask. As seen in the graph a concentration of 3:1 parts H₂SO₄:H₃PO₄ provides the highest etching rate. It should be appreciated that observations have shown that H₂SO₄:H₃PO₄ ratio at 1:1, although having a lower etch rate than the higher ratios such as 3:1, yield a smoother surface with less pits. While the physical mechanism is not known, however, it is speculated that the slower etch rate does not allow the defects to be preferentially etched, which is the source the pitting. The defects may be crystal disruptions or metallic contamination. Accordingly, in at least one embodiment the H₂SO₄:H₃PO₄ ratio is 3:1. In at least one alternative embodiment the H₂SO₄:H₃PO₄ ratio at 1:1.

Smoothing may be performed on any sapphire crystal substrate that has undergone a grinding, lapping, or polishing step. During the polishing step, the top layers of the sapphire crystal, independent of initial crystal orientation are disrupted. This lattice disruption is noticed in a variety of single crystal substrates (J. A. Randi, J. C. Lambropoulos, and S. D. Jacobs, “Subsurface damage in some single crystalline optical materials,” Appl. Opt., 44, 2241-2249 (2005) http://www.opticsinfobase.org/ao/abstract.cfm?URI=ao-44-12-2241). These crystal disruptions affect the optical and mechanical properties of the substrate. The disrupted lattice layers on sapphire substrates can be removed using the smoothing process. In some cases, no more than 2 microns sapphire is removed. Improved reflectivity is achieved and are shown in the following table, approximately 2-4 microns of sapphire is removed in each example.

| Film | Smoothing Result after mechanical polishing |
|---|---|
| Al₂O₃ (0001 - c-plane) | 77% improvement in reflectivity |
| Al₂O₃ (1102 - r-plane) | 88% improvement in reflectivity |
| Al₂O₃ (1120 - a-plane) | XX% visible improvement |

H₂SO₄ alone deposits Al₂(SO₄)₃ on the surface, even with agitation and at all temperatures, this chemistry alone is not acceptable for thinning or smoothing. In addition, ratio of 5:1 H₂SO₄ is the cut off for forming sulfates on the surface of the sapphire. Above 5:1, for example 8:1 form the sulfate precipitation. It has been found that if the sulfate precipitation occurs, placing the substrate into high temperature H₃PO₄ or into a H₂SO₄+H₃PO₄ bath at lower ratios, such as 3:1, the precipitation can be removed.

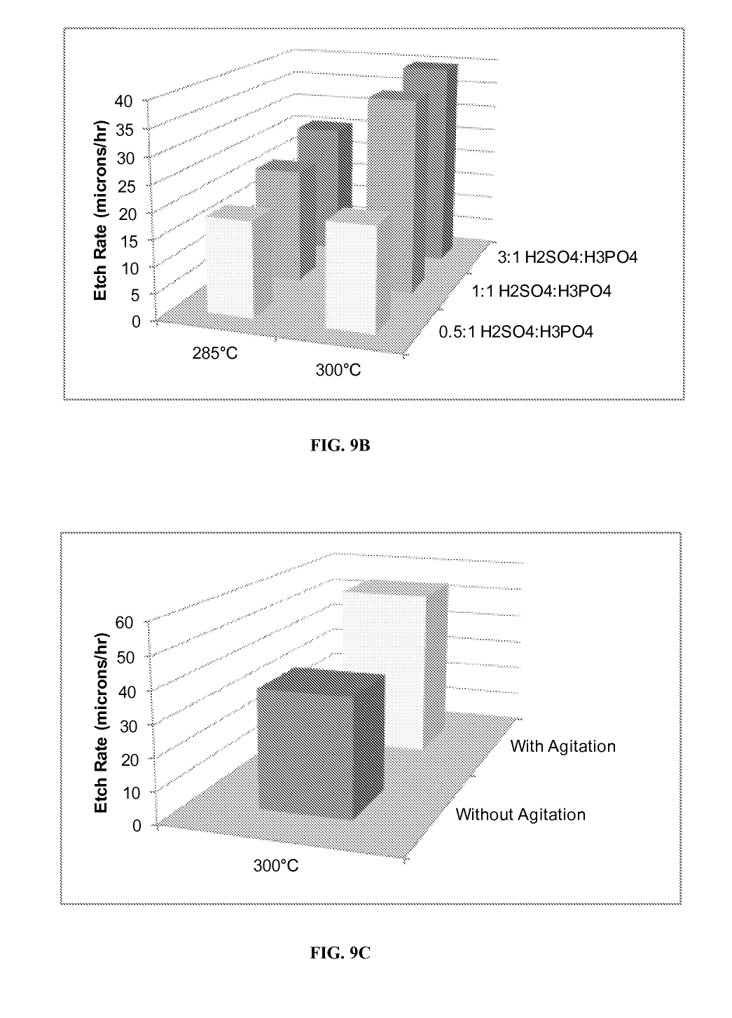

FIG. 9A illustrates etching rates for sapphire substrate thinning (SST) and sapphire substrate smoothing (SST) with respect to temperature (both sides of the substrate are being etched). Thinning and smoothing etching rate is dependent on concentration, temperature, and sapphire purity, and crystal orientation. As shown in FIG. 9A, of the conditions shown, a solution of 3:1 parts by volume H₂SO₄:H₃PO₄ and 300° C. achieves the highest thinning etch rate for the c-plane DSP. It is noted that while in the present example the temperature target is 300° C., with appropriate equipment modifications; for example thicker quartz tank and other tank changes, a higher temperature of up to 400° C. is possible. It is understood that higher temperatures yield higher etch rates and can etch various orientations of sapphire that are not defined clearly; such as the edges of the boule after cutting but before the substrates are sliced. The orientations are not c- and a-plane, for example. The higher temperature allows rapid processing when pitting reduction or perfect smoothing is not required, thus working at temperatures in excess of 300° C. improves throughput. Smoothing can be accomplished with the same chemistry as thinning Lower temperatures, and thus lower etching rates are desirable due to the thin layer to be removed. In both cases the goal is to minimize the amount of pitting that occurs.

FIG. 9B illustrates etching rates for c-plane sapphire substrate thinning (SST) and sapphire substrate smoothing with respect to concentration at 285 and 300° C. Depending on the amount of material to be removed and the purity of the sapphire crystal, plus the degree of surface roughness that can be tolerated, all conditions are acceptable to thinning

FIG. 9C illustrates c-plane etching rates for sapphire substrate thinning (SST) and sapphire substrate smoothing (SSS) with respect to agitation and no agitation at 300° C. In addition to thinning at a fast etch rate, the agitation improves smoothing.

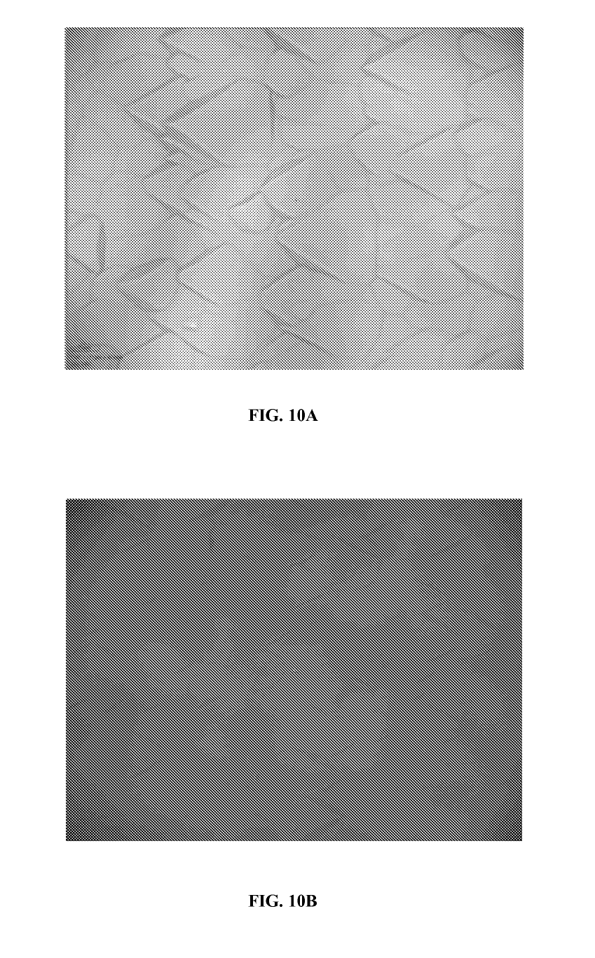

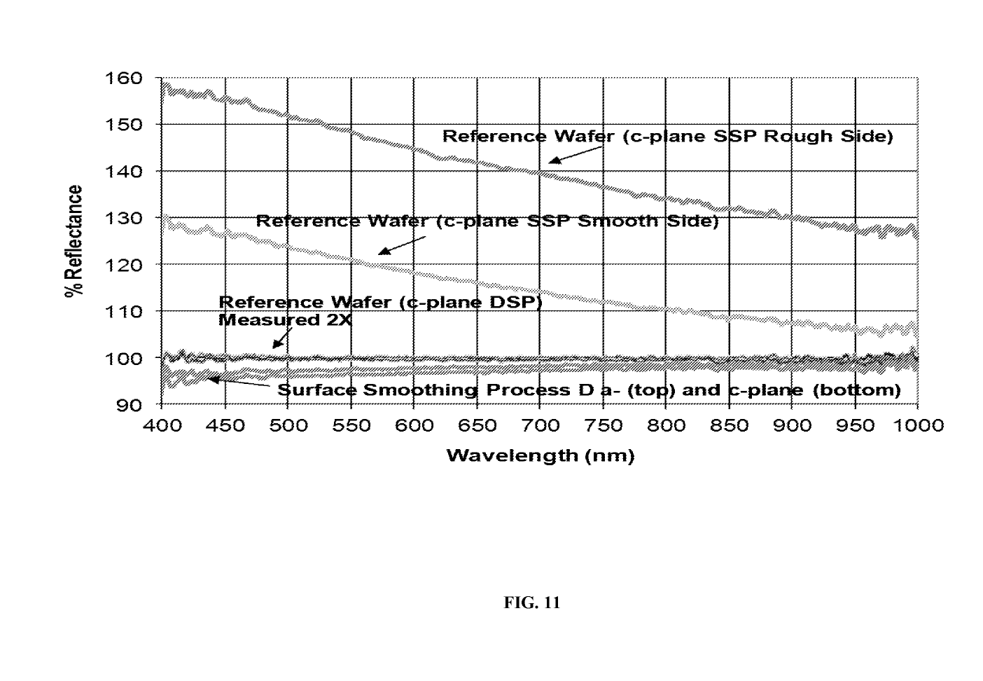

FIG. 10A and FIG. 10B illustrate surfaces for c-plane sapphire substrate smoothing (SSS) with and without agitation. FIG. 10B shown the melding together of the crystal facets of the sapphire surface, while FIG. 10A clearly shows the facets delineated. The surface roughness values are shown below that indicates the agitation can improve the surface roughness and render a surface with low-density pits and peaks.

| Metric | Ra | Rrms |
|---|---|---|
| As cut | 0.6883 | 0.8715 |
| Without agitation | 0.7311 | 0.9481 |
| With agitation | 0.6753 | 0.8103 |

### EXAMPLES

The present invention is further detailed with respect to the following examples that are not intended to limit the scope of the claimed invention, but rather to illustrate specific aspects of the invention.

### Example 1

A patterned sapphire substrates (PSS) is processed using a wet etch composed of 66-75 volume % of 98 weight % H₂SO₄ and 25-33 volume % of 85 weight % H₃PO₄ at a temperature ranging between 250-400° C. Example results are shown in table 1.

TABLE 1

| Film | Etching Rate above 280° C. | |
|---|---|---|
| Al₂O₃ (0001) | ~10-12.0 | μm/hr |
| GaN | ~2.9 | μm/hr |
| SiO₂ | <<0.01 | μm/hr |
| Si | <<0.01 | μm/hr |

| | |
|---|---|
| Photoresist | Reacts in bath |

### Example 2

Sapphire substrate smoothing (SSS) is processed using a wet etch composed of 30-90 volume % of 98 weight % H₂SO₄ and 10-70 volume % of 85 weight % H₃PO₄ at a temperature ranging between 250-300° C. It is noted that further reductions in sulfuric acid or phosphoric concentrations are possible. In one embodiment only sulfuric acid is used for smoothing, where no etching was observed. Example results are shown in table 2.

TABLE 2

| Film | Etching Rate at or above 270° C. | |
|---|---|---|
| Al₂O₃ (0001) | ~14-18 | μm/hr |
| Al₂O₃ (1120) | </=5 | μm/hr |

### Example 3

Sapphire substrate thinning (SST) is performed using a wet etch composed of 30-90 volume % of 98 weight % H₂SO₄ and 10-70 volume % of 85 weight % H₃PO₄ at a temperature ranging between 250-300° C. It is noted that further reductions in concentrations are possible. Example results are shown in table 3.

TABLE 3

| Film | Etching Rate at or above 280° C. | |
|---|---|---|
| Al₂O₃ (0001) | ~30-54 | μm/hr |
| Al₂O₃ (1120) | <5 | μm/hr |

The foregoing description is illustrative of particular embodiments of the invention, but is not meant to be a limitation upon the practice thereof. The following claims, including all equivalents thereof, are intended to define the scope of the invention.

1. A method for thinning a sapphire substrate, said method comprising:
placing said sapphire substrate in a pre-heat tank to raise the temperature of said sapphire substrate;
placing said pre-heated sapphire substrate in a wet etch tank comprising a solution including at least one of H₂SO₄ and H₃PO₄ at a temperature ranging between 200-400° C.;
monitoring time to determine when to remove said sapphire substrate from said wet etch tank to thin said sapphire substrate; and
placing said sapphire substrate in a cool-down tank to lower the temperature of said sapphire substrate.

2. The method of claim 1 wherein said sapphire substrate is thinned on the substrate c-plane.

3. The method of claim 1 wherein said H₂SO₄ and H₃PO₄ are present in a volume ratio of between 0.1-10:1.

4. The method of claim 1 wherein said solution is a 30-90 volume % of 96-98 wt % H₂SO₄ and 10-70 volume % of 85 wt % H₃PO₄.

5. The method of claim 1 wherein said substrate is an as-cut wafer or as ground wafer.

6. The method of claim 1 wherein said substrate has an etch rate of more than 18 microns per hour for a crystal plane (0001).

7. The method of claim 1 further comprising agitating said substrate while in said wet etch tank.

8. A system for producing sapphire substrates, said system comprising:
a docking base station configured to accept docking modules and controls;
a single point for facility connections to utilities and supply lines on said docking base station; and
wherein said docking modules comprise one or more high temperature process modules, a pre-heat module, a cooling module, and a dryer/rinse module.

9. The system of claim 8 wherein said one or more high temperature process modules are etching tanks configured to operate in a range of 200-400° C.

10. A composition comprising:
a sapphire substrate having a thickness of between 50 and 400 microns and a reflectance of at wavelengths between 380 nm and 1000 nm.

11. A method for smoothing a sapphire substrate, said method comprising:
placing said sapphire substrate in a pre-heat tank to raise the temperature of said sapphire substrate;
placing said pre-heated sapphire substrate in a wet etch tank comprising a solution including at least one of H₂SO₄ and H₃PO₄ at a temperature ranging between 200-400° C.;
monitoring time to determine when to remove said sapphire substrate from said wet etch tank to smooth said substrate; and
placing said sapphire substrate in a cool-down tank to lower the temperature of said sapphire substrate.

12. The method of claim 11 wherein said sapphire substrate is smoothed c-plane.

13. The method of claim 11 wherein said H₂SO₄ and H₃PO₄ are present in a volume ratio of between 0.1-10:1.

14. The method of claim 11 wherein said solution is a 30-90 volume % of 96-98 wt % H₂SO₄ and 10-70 volume % of 85 wt % H₃PO₄.

15. The method of claim 11 wherein said substrate is an as-cut wafer or as ground wafer or as lapped or polished wafer.

16. The method of claim 11 wherein said substrate has an etch rate of more than 10 microns per hour for a crystal plane (0001).

17. The method of claim 11 further comprising agitating said substrate while in said wet etch tank.
